(19) United States
(12) Patent Application Publication
(10) Pub. No.: US 2026/0101725 A1
(43) Pub. Date: Apr. 9, 2026

(54) SEMICONDUCTOR DEVICE, TESTING SYSTEM, AND METHOD FOR TESTING DEVICE UNDER TEST ON SEMICONDUCTOR WAFER

(71) Applicant: AP MEMORY TECHNOLOGY CORPORATION, HSINCHU COUNTY (TW)

(72) Inventor: WENLIANG CHEN, HSINCHU COUNTY (TW)

(21) Appl. No.: 18/910,368

(22) Filed: Oct. 9, 2024

(51) Int. Cl. G01R 31/265; G01R 31/319; H02J 50/00; H02J 50/20; H10B 80/00

(52) U.S. Cl. CPC H10P 74/27; H02J 50/001; H02J 50/20; H10B 80/00

(57) ABSTRACT

A semiconductor device includes a semiconductor wafer, an antenna element and a radio frequency (RF) transponder. The semiconductor wafer includes a plurality of regions. Each region includes one or more dies. The antenna element is disposed in one of the regions where a device under test (DUT) is disposed. The antenna element is arranged to couple an RF signal into an electrical signal. The RF transponder is disposed in the one of the regions, and coupled to the antenna element and the DUT. The RF transponder is configured to send a stimulus signal to the DUT in response to the electrical signal, and drive the antenna element to output a modulated RF signal according to a response signal received from the DUT. The response signal is generated from the DUT in response to the stimulus signal. The modulated RF signal is indicative of a behavior of the DUT.

### BACKGROUND

The present disclosure relates to wafer testing, and more particularly, to a semiconductor device provided for contactless testing, a testing system and a method for testing a device under test on a semiconductor wafer.

In the semiconductor industry, probe testing is a critical testing method used to conduct electrical tests on individual dies during the wafer manufacturing process. For example, with the help of a probe card, tiny probes make contact with specific points on a semiconductor wafer or chip, allowing power and test signals to be delivered while measuring the response. This testing method can help manufacturers evaluate the functionality and performance of wafers/chips during the manufacturing process. Thus, the manufacturers can ensure that their products meet design specifications. In addition, probe testing may be performed in the later stages of wafer manufacturing to identify and discard defective chips before they proceed to more expensive packaging steps, thereby improving yield and overall manufacturing efficiency.

### SUMMARY

The described embodiments provide a semiconductor device provided for contactless testing, a testing system and a method for testing a device under test on a semiconductor wafer.

Some embodiments described herein may include a semiconductor device. The semiconductor device includes a first semiconductor wafer, an antenna element, and a radio frequency (RF) transponder. The first semiconductor wafer includes a plurality of regions. Each of the regions includes one or more dies. The antenna element, disposed in one of the regions where a device under test (DUT) is located, is arranged to couple an RF signal into an electrical signal. The RF transponder is disposed in the one of the regions and coupled to the antenna element and the DUT. The RF transponder is configured to send a stimulus signal to the DUT in response to the electrical signal received from the antenna element, and drive the antenna element to output a modulated RF signal according to a response signal received from the DUT. The response signal is generated from the DUT in response to the stimulus signal. The modulated RF signal is indicative of a behavior of the DUT.

Some embodiments described herein may include a testing system. The testing system includes a first semiconductor wafer, a radio frequency (RF) reader, an antenna element and an RF transponder. The first semiconductor wafer includes a plurality of regions. Each of the regions comprises one or more dies. The RF reader is arranged for sending a wireless interrogation signal to the first semiconductor wafer. The antenna element, disposed in one of the regions where a device under test (DUT) is located, is arranged to couple the wireless interrogation signal into an electrical signal. The RF transponder is disposed in the one of the regions and coupled to the antenna element and the DUT. The RF transponder is configured to send a stimulus signal to the DUT in response to the electrical signal, and drive the antenna element to output a modulated RF signal according to a response signal received from the DUT. The response signal is generated from the DUT in response to the stimulus signal. The modulated RF signal is reflected from the antenna element back to the RF reader.

Some embodiments described herein may include a method for testing a device under test (DUT) on a semiconductor wafer. The method includes: coupling a wireless interrogation signal into an electrical signal through an antenna element; utilizing a transponder disposed on the semiconductor wafer to receive the electrical signal and accordingly apply a stimulus signal to the DUT, wherein a response signal is outputted from the DUT in response to the stimulus signal; and modulating a reply signal, reflected from the antenna element in response to the wireless interrogation signal, according to the response signal, wherein the reply signal is indicative of a behavior of the DUT.

With the use of the proposed non-contact testing scheme, the behavior/function of the DUT can be evaluated without touching the surface of the semiconductor wafer, thereby maintaining good wafer surface flatness. In addition, the proposed non-contact testing scheme not only uses simplified circuit components, but also delivers power required by the DUT through wireless power transmission, eliminating the cost of implementing power supply circuits on the semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagram illustrating an exemplary testing system in accordance with some embodiments of the present disclosure.

FIG. 1B illustrates an implementation of the semiconductor wafer shown in FIG. 1A in accordance with some embodiments of the present disclosure.

FIG. 2 illustrates an implementation of the testing system shown in FIG. 1A in accordance with some embodiments of the present disclosure.

FIG. 3 is a block diagram of the transponder shown in FIG. 2 in accordance with some embodiments of the present disclosure.

FIG. 4 illustrates an implementation of the device under test shown in FIG. 2 in accordance with some embodiments of the present disclosure.

FIG. 5 illustrates an implementation of the transponder shown in FIG. 2 in accordance with some embodiments of the present disclosure.

FIG. 6 illustrates an implementation of the testing system shown in FIG. 1A in accordance with some embodiments of the present disclosure.

FIG. 7A illustrates an implementation of the testing system shown in FIG. 1A in accordance with some embodiments of the present disclosure.

FIG. 7B illustrates an implementation of the testing system shown in FIG. 1A in accordance with some embodiments of the present disclosure.

FIG. 8 is a diagram illustrating a workflow for integrating non-contact testing into wafer-on-wafer bonding in accordance with some embodiments of the present disclosure.

FIG. 9 is a flowchart of an exemplary method for testing a device under test on a semiconductor wafer in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

Moreover, spatially relative terms, such as “below,” “above,” “left,” “right,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As probe testing depends on contact between a probe and a chip for testing, it becomes ineffective when the probe cannot physically reach the chip. For example, probes of a probe card need to make physical contact with test points via on a wafer. Thus, when a wafer is still in the manufacturing stage and does not yet have contact openings, probe testing is not possible. Additionally, probe contact may damage the wafer surface or cause surface unevenness, which can be detrimental to subsequent processes that require high surface quality of wafers or dies. For example, in processes where multiple wafers are stacked or bonded, good flatness of the wafer surface is necessary to ensure stronger bonding. Conducting probe testing on a wafer before stacking it with another wafer can significantly reduce the quality of the stacked wafers.

Moreover, after multiple wafers are stacked, a device under test (DUT) may be located between adjacent wafers in a wafer stack. As probes cannot reach an area sandwiched between adjacent wafers (i.e., an area where the DUT is located), probe testing becomes impractical for evaluating the behavior of the DUT.

The present disclosure provides exemplary semiconductor devices that can evaluate the behavior/performance of DUTs on a semiconductor wafer without the need for probe contact. In addition, the present disclosure provides exemplary non-contact wafer testing systems and methods that address the issues of contact-based probe testing. For example, the proposed non-contact testing scheme may use a radio frequency (RF) reader, along with an antenna element and a transponder on a semiconductor wafer, to assess the function, behavior or performance of the DUTs on the semiconductor wafer in a non-contact manner. Further description is provided below.

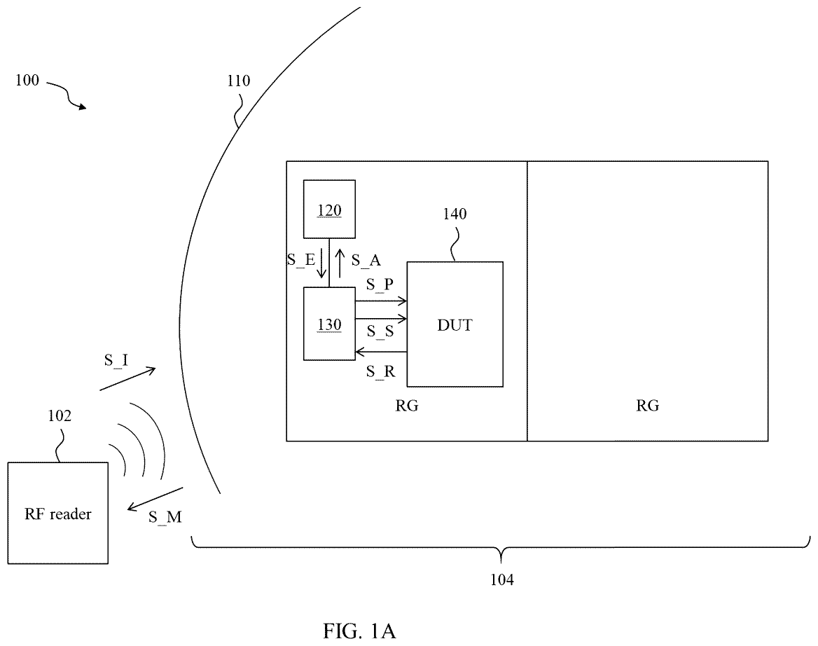

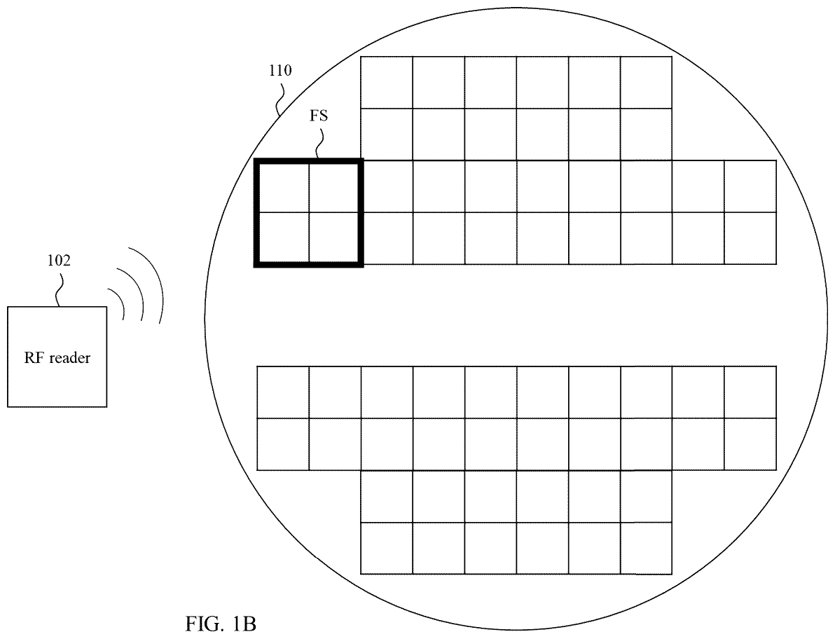

FIG. 1A is a diagram illustrating an exemplary testing system in accordance with some embodiments of the present disclosure. The testing system 100 includes, but is not limited to, an RF reader 102 and a semiconductor device 104. The testing system 100 utilizes the RF reader 102 to send a wireless interrogation signal S_I (i.e., an RF signal) to the semiconductor device 104 for non-contact testing of a DUT 140 in the semiconductor device 104. The wireless interrogation signal S_I may indicate, but is not limited to, test parameters, test conditions, and/or test modes for evaluating the function/behavior of the DUT 140. The DUT 140 may be a single chip/die, multiple chips/dies, or a portion of a chip/die, such as (but not limited to) a memory cell array. The non-contact testing performed by the testing system 100 may include, but is not limited to, functional verification, electrical performance testing, defect detection, and reliability assessment.

In the present embodiment, the semiconductor device 104 includes, but is not limited to, a semiconductor wafer 110, an antenna element 120, and a transponder 130. The semiconductor wafer 110 is a complete wafer (e.g. an uncut wafer). In some examples, the semiconductor wafer 110 is a portion of a complete wafer (e.g. a diced wafer). The semiconductor wafer 110 includes a plurality of regions RG. Each region RG may include one or more dies (or chips). In some examples, the region RG is an area occupied by a single die; in some examples, the region RG is an area formed by multiple dies; in some examples, each region RG has a size that may be equal to a field size of a reticle used in fabricating the semiconductor wafer 110.

FIG. 1B illustrates an implementation of the semiconductor wafer 110 shown in FIG. 1A in accordance with some embodiments of the present disclosure. Referring to FIG. 1B, in the process of fabricating the semiconductor wafer 110, a reticle with a field size FS may be used to transfer the circuit pattern onto the semiconductor wafer 110, forming multiple dies on the semiconductor wafer 110. The field size FS corresponds to an area on the semiconductor wafer 110 that can be projected by the reticle during each exposure, and therefore can determine the number of dies generated on the semiconductor wafer 110 during each exposure. The area corresponding to the field size FS may represent an embodiment of the region RG shown in FIG. 1A. By way of example but not limitation, the field size FS may be equal to a size of an area covered by 2-by-2 dies, and the region RG shown in FIG. 1A may include four dies. In some examples, the field size FS may be equal to a size of an area covered by i-by-j (where both i and j are positive integers) dies, and the region RG shown in FIG. 1A may include i×j dies.

Referring again to FIG. 1A, the antenna element 120 is disposed in the region RG where the DUT 140 is located, and is arranged to couple the wireless interrogation signal S_I into an electrical signal S_E. The electrical signal S_E may carry the test information indicated by the wireless interrogation signal S_I, such as the test parameters, test conditions, and/or test modes used to evaluate the function of the DUT 140. The antenna element 120 may be formed from a conductive material (e.g. a metal material) and fabricated using photolithography. For example, the antenna element 120 may be a metal thin film layer positioned near the edge of the region RG.

The transponder 130 is disposed in the region RG where the DUT 140 is located, and is coupled to the antenna element 120 and the DUT 140. The transponder 130 is configured to receive the electrical signal S_E from the antenna element 120, and generate a stimulus signal S_S in response to the electrical signal S_E. The transponder 130 may send the stimulus signal S_S to the DUT 140, and accordingly trigger the DUT 140 to generate a response signal S_R. In other words, the response signal S_R is generated from the DUT 140 in response to the stimulus signal S_S. For example, the stimulus signal S_S may trigger the DUT 140 to operate in a test scenario, and the response signal S_R may reflect the function and performance of the DUT 140 in that test scenario.

In addition, the transponder 130 is configured to receive the response signal S_R from the DUT 140, and drive the antenna element 120 to output a modulated RF signal S_M according to the response signal S_R. The modulated RF signal S_M can indicate or reflect the behavior of the DUT 140 (i.e., the characteristics exhibited during the test). In some embodiments, the transponder 130 can be configured to generate the electrical signal S_A according to the response signal S_R, and send the electrical signal S_A to drive the antenna element 120 to output the modulated RF signal S_M.

By way of example but not limitation, in some cases where the modulated RF signal S_M changes in response to a change in a load impedance on the antenna element 120, the transponder 130 may adjust the load impedance on the antenna element 120 according to the response signal S_R, thereby adjusting the modulated RF signal S_M so that it conveys the information carried by the response signal S_R. In other words, the transponder 130 can change reflection coefficient of an incoming RF signal that is incident on the antenna element 120 (i.e., the wireless interrogation signal S_I) by modulating the load impedance on the antenna element 120, and accordingly drive the antenna element 120 to output the modulated RF signal S_M. In some other cases where the modulated RF signal S_M changes in response to a change in an input impedance of the antenna element 120 as seen by the incident wireless interrogation signal S_I, the transponder 130 may adjust the input impedance of the antenna element 120 according to the response signal S_R, thereby adjusting the modulated RF signal S_M.

In some other cases where impedance characteristics of the antenna element 120 are adjustable, the transponder 130 can generate the electrical signal S_A according to the response signal S_R, thereby altering the impedance characteristics and adjusting the modulated RF signal S_M. Alternatively, the transponder 130 may generate the electrical signal S_A according to the response signal S_R, and the antenna element 120 may convert this electrical signal into the modulated RF signal S_M, which can convey the information carried by the response signal S_R.

To facilitate understanding of the present disclosure, some embodiments are given below to further describe the proposed non-contact testing scheme. However, these embodiments are not intended to limit the scope of the present disclosure. Other embodiments that adopt the testing architecture shown in FIG. 1A are within the scope of the present disclosure.

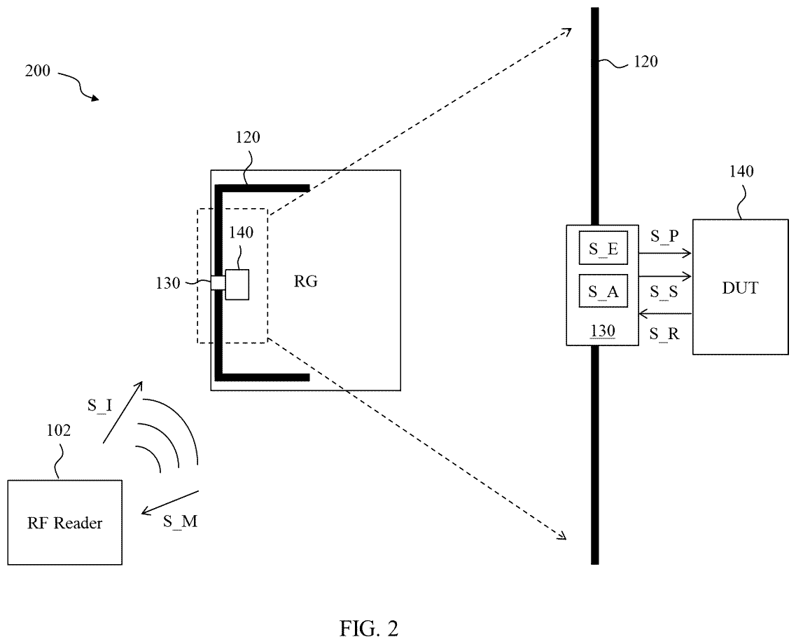

FIG. 2 illustrates an implementation of the testing system 100 shown in FIG. 1A in accordance with some embodiments of the present disclosure. In the present embodiment, the testing system 200 may use higher frequency RF signals to test the DUT 140, allowing the RF reader 102 to be located farther away from the DUT 140 (or the semiconductor device 104). By way of example but not limitation, the wireless interrogation signal S_I may be an RF signal in the ultra-high frequency (UHF) or super high frequency (SHF) bands, and the antenna element 120 may be implemented with a structure capable of transmitting RF signals in the UHF/SHF bands. In the embodiment shown in FIG. 2, the antenna element 120 may be, but is not limited to, a dipole antenna, which can be implemented using a metal thin film layer positioned near the edge of the region RG. In addition, the frequency of the wireless interrogation signal S_I may fall within an unlicensed band in the UHF/SHF spectrum.

In operation, the RF reader 102 may send an RF signal (i.e., the wireless interrogation signal S_I) for testing the DUT 140, and access the data of the DUT 140 via the antenna element 120 and the transponder 130. For example, the RF signal sent by the RF reader 102 is converted into the electrical signal S_E via the antenna element 120. The transponder 130 may deliver power to the DUT 140 according to the electrical signal S_E. In other words, even if no power supply circuit is disposed on the semiconductor wafer 110, the DUT 140 can still obtain the power required for test operations. The proposed non-contact testing scheme can save the cost of implementing a power supply circuit on the semiconductor wafer. In addition, the transponder 130 may generate the stimulus signal S_S according to the electrical signal S_E, and accordingly trigger the DUT 140. In response to the stimulus signal S_S, the DUT 140 may generate the corresponding response signal S_R.

Next, the transponder 130 may drive the antenna element 120 to output the modulated RF signal S_M according to the response signal S_R. In the present embodiment, when the RF signal sent by the RF reader 102 is incident on the antenna element 120, a reflected signal can be reflected from the antenna element 120 back to the RF reader 102. The transponder 130 may modulate the reflected signal according to the response signal S_R and accordingly generate the modulated RF signal S_M, which is reflected back to the RF reader 102 from the antenna element 120. For example, the transponder 130 may adjust the load impedance on the antenna element 120 according to the response signal S_R, thereby adjusting the reflection coefficient of the antenna element 120 to alter the reflected signal (i.e., the modulated RF signal S_M) reflected from the antenna element 120. In addition, the RF reader 120 may receive the modulated RF signal S_M, and generate a test result of the DUT 140 according to the modulated RF signal S_M.

Note that the above description is provided for illustrative purposes, and is not intended to limit the scope of the present disclosure. In some embodiments, the transponder 130 may modulate the electrical signal S_E according to the response signal S_R to generate the electrical signal S_A, which is converted into the modulated RF signal S_M via the antenna element 120 and sent to the RF reader 102. In some embodiments, antenna element(s) (e.g., the antenna element 120) and transponder(s) (e.g., the transponder 130) can be disposed in other region(s) (e.g., one or more regions RG shown in FIG. 1A) of the semiconductor wafer 110 for testing DUT(s). In some embodiments, the region RG may be a self-defined region, which is different from a region corresponding to a field size of a reticle).

With the use of the proposed non-contact testing scheme, the behavior/function of the DUT can be evaluated without touching the surface of the semiconductor wafer, thereby maintaining good wafer surface flatness. In addition, the proposed non-contact testing scheme not only uses simplified circuit components, but also delivers power required by the DUT through wireless power transmission, eliminating the cost of implementing power supply circuits on the semiconductor wafer.

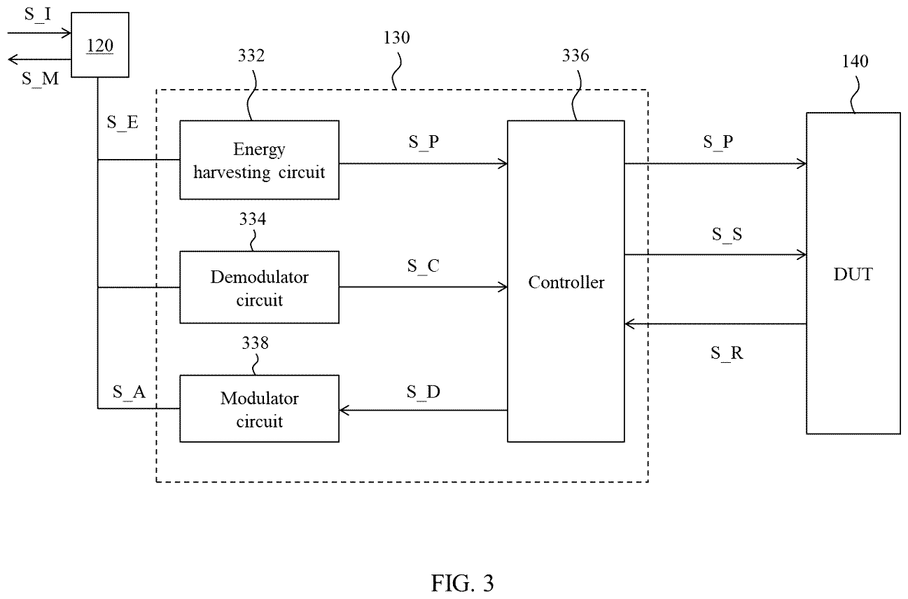

FIG. 3 is a block diagram of the transponder 130 shown in FIG. 2 in accordance with some embodiments of the present disclosure. The transponder 130 shown in FIG. 1A can also be implemented using the architecture shown in FIG. 3. In the embodiment shown in FIG. 3, the transponder 130 includes, but is not limited to, an energy harvesting circuit 332, a demodulator circuit 334, a controller 336 and a modulator circuit 338.

The energy harvesting circuit 332, coupled to the antenna element 120, is configured to capture energy from the electrical signal S_E to generate a power signal S_P. By way of example but not limitation, the energy harvesting circuit 332 can rectify the captured energy to produce a direct current (DC) voltage signal, which can serve as the power signal S_P. In some embodiments, the energy harvesting circuit 332 can be configured to store the captured energy in a capacitor or other energy storage components.

The demodulator circuit 334, coupled to the antenna element 120, is configured to demodulate the electrical signal S_E to generate a command signal S_C. By way of example but not limitation, the command signal S_C can be a low-frequency signal demodulated from the electrical signal S_E; as another example, the command signal S_C can include test instructions (e.g., read/write commands for memory access) and test data (e.g., memory addresses to be accessed); as another example, the command signal S_C can trigger a leakage current test on a transistor.

The controller 336 is coupled to the energy harvesting circuit 332, the demodulator circuit 334 and the DUT 140. The controller 336 is configured to be activated by the power signal S_P and further provide the power signal S_P to the DUT 140, and process the command signal S_C to generate the stimulus signal S_S. In addition, the controller 336 can send the stimulus signal S_S to the DUT 140 to trigger the DUT 140, and receive the corresponding response signal S_R generated by the DUT 140. For example, the stimulus signal S_S can enable the DUT 140 to perform a memory access operation, and the response signal S_R can indicate a memory access result. As another example, the stimulus signal S_S can trigger a leakage current test on a transistor of the DUT 140, and the response signal S_R can correspond to a leakage current of the transistor. The power signal S_P is the power source of DUT 140 to perform the test scenario aforementioned. In the present embodiment, the controller 336 can process the response signal S_R to generate a data signal S_D, which can represent or reflect the behavior of the DUT 140. The controller 336 can be implemented as a digital controller.

The modulator circuit 338, coupled between the antenna element 120 and the controller 336, is configured to drive the antenna element 120 to output the modulated RF signal S_M according to the data signal S_D. For example, the modulator circuit 338 can adjust the load impedance on the antenna element 120 by switching between different impedance states according to the data signal S_D, and accordingly drive the antenna element 120 to output the modulated RF signal S_M. In other words, the modulator circuit 338 can adjust the load impedance on the antenna element 120 according to the data signal S_D, thereby modulating an RF signal (which is reflected from the antenna element 120 back to the RF reader 102) to produce the modulated RF signal S_M.

In some embodiments, the modulator circuit 338 can generate the electrical signal S_A that reflects the behavior of the DUT 140 according to the data signal S_D. The generated electrical signal can be converted into the modulated RF signal S_M through the antenna element 120, and transmitted to the RF reader 102.

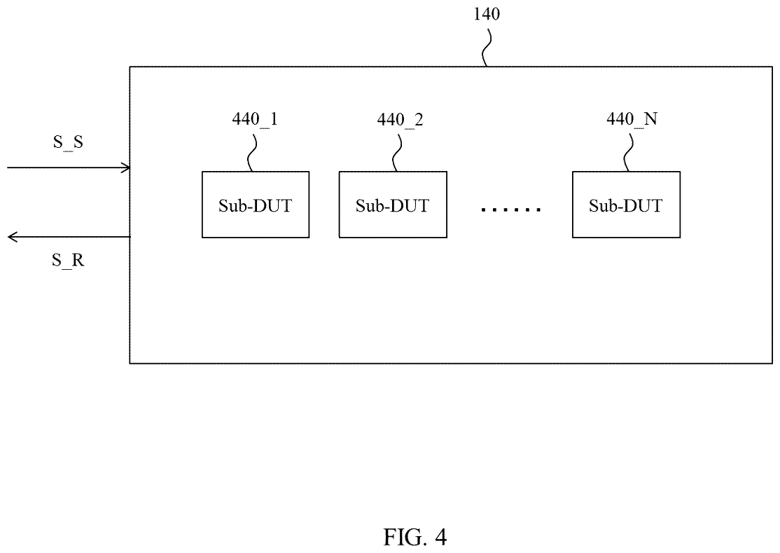

FIG. 4 illustrates an implementation of the DUT 140 shown in FIG. 2 in accordance with some embodiments of the present disclosure. The DUT 140 shown in FIG. 1A can also be implemented using the architecture illustrated in FIG. 4. In the embodiment shown in FIG. 4, the DUT 140 may include N sub-units under test (sub-DUTs) 440_1 to 440_N, where N is greater than 1. The N sub-DUTs 440_1 to 440_N can individually be triggered by the stimulus signal S_S. For example, when the transponder 130 shown in FIG. 1A (or the controller 336 shown in FIG. 3) activates the sub-DUTs 440_1 according to the stimulus signal S_S, the sub-DUT 440_2 can remain in an inactivated state. As another example, when the transponder 130 shown in FIG. 1A (or the controller 336 shown in FIG. 3) activates the sub-DUT 440_1 according to the stimulus signal S_S, the other sub-DUTs 440_2 to 440_N can remain in an inactivated state. As each the sub-DUT can be activated individually, the power provided to the DUT 140 can be reduced, thereby saving power consumption. In some embodiments, the sub-DUTs 440_1 to 440_N share the same set of circuits for testing (e.g., the antenna element 120 and the transponder 130 in FIG. 3). In some embodiments, sharing the same set of circuits for testing the multiple sub-DUTs can reduce the area required to test each sub-DUTs. Different sub-DUTs are configured to be activated and tested by different stimulus signals S_S.

In some embodiments, the DUT 140 can be a memory circuit, where a sub-DUT can be a memory array, memory peripheral circuit, memory cell, a transistor, multiple transistors, or other circuit units included in the memory circuit. In some embodiments, the DUT 140 shown in FIG. 3 can be implemented using the architecture illustrated in FIG. 4.

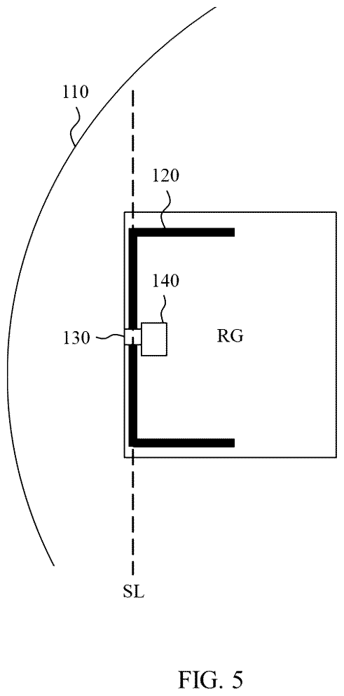

FIG. 5 illustrates an implementation of the transponder 130 shown in FIG. 2 in accordance with some embodiments of the present disclosure. In the present embodiment, the transponder 130 can be positioned near the edge of region RG, without occupying the space required for the dies. For example, the transponder 130 can be located in the scribe line SL on the semiconductor wafer 110. In addition, if the transponder 130 is located in the scribe line SL, it can be removed or destroyed during the subsequent wafer dicing operation to prevent the leakage of confidential data stored in the transponder 130 (e.g., test parameters or other internal test data). In some embodiments, the transponder 130 shown in FIG. 1A can also be placed near the edge of region RG or in a scribe line on the semiconductor wafer 110. In some embodiments, the region RG includes multiple dies, and each die includes one antenna element 120, one transponder 130 and one DUT 140. The scribe lines SL are located between each two of the dies. The transponder 130 of each die can be placed on nearby scribe line.

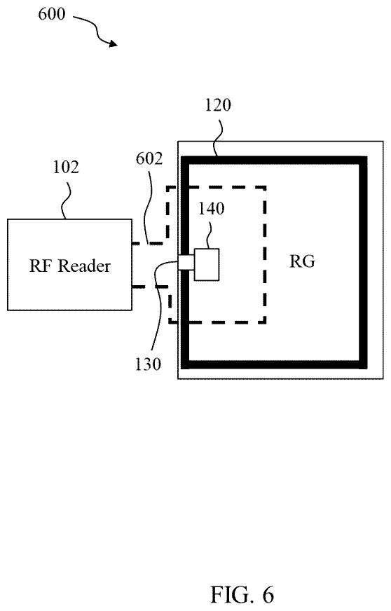

FIG. 6 illustrates an implementation of the testing system 100 shown in FIG. 1A in accordance with some embodiments of the present disclosure. The structure of the testing system 600 can be substantially identical to that of the testing system 200 shown in FIG. 2 except for the inductive coupler 602. The inductive coupler 602 can be arranged to inductively couple the wireless interrogation signal S_I sent by the RF reader 102 to the antenna element 120. In some embodiments, the inductive coupler 602 is integrated in the RF reader 102. The transponder 130 and the RF reader 102 interact by inductive coupling, for example but not limitation, near-field coupling below 100 MHz frequency.

In the embodiment shown in FIG. 6, the frequency of the RF signal used by the testing system 600 can be lower than that used by the testing system 200 shown in FIG. 2, and the RF reader 102 can be close to but not in contact with the semiconductor device 104 (or the DUT 140) during test operation. By way of example but not limitation, the wireless interrogation signal S_I can be an RF signal in the high-frequency (HF) band, and the antenna element 120 can be implemented with a structure capable of transmitting RF signals in the HF band. In the example shown in FIG. 6, the antenna element 120 can be, but is not limited to, a loop antenna, which can be implemented using a metal thin film layer positioned at the edge of the region RG. In addition, the frequency of the wireless interrogation signal S_I can fall within an unlicensed band in the high-frequency spectrum.

As those skilled in the art can appreciate the operation of the testing system 600 after reading the above paragraphs directed to FIG. 1A to FIG. 5, further description is omitted here for brevity.

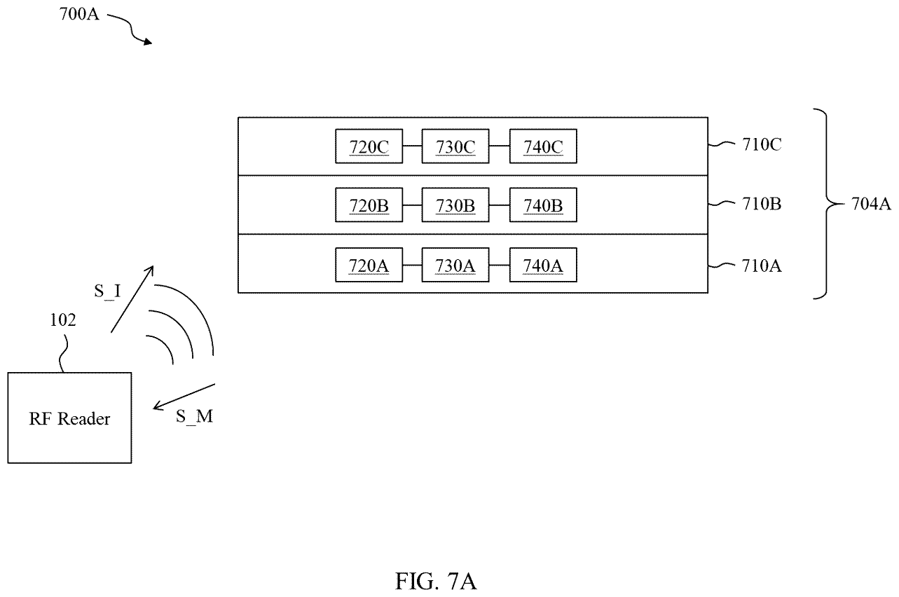

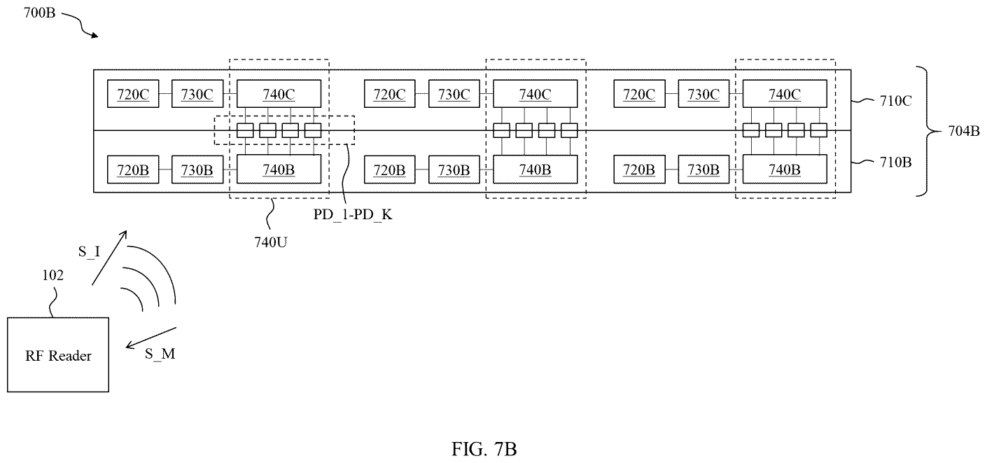

The proposed non-contact testing scheme can test not only DUTs that are visible from the outside, but also DUTs that are not visible from the outside. FIG. 7A illustrates an implementation of the testing system 100 shown in FIG. 1A in accordance with some embodiments of the present disclosure. The testing system 700A includes the RF reader 102 shown in FIG. 1A and a semiconductor device 704A. The semiconductor device 704A includes, but is not limited to, multiple semiconductor wafers 710A to 710C stacked together, at least one of which can be implemented using the semiconductor wafer 110 shown in FIG. 1A. In addition, the antenna element and the transponder used in the proposed testing scheme can be disposed on at least one of the semiconductor wafers 710A to 710C.

The semiconductor wafers 710A to 710C can form a wafer stack using wafer-on-wafer (WoW) technology. For example, each of the semiconductor wafers 710A to 710C can be a memory wafer containing multiple memory dies. As another example, each of the semiconductor wafers 710A and 710B can be a memory wafer containing multiple memory dies, while the semiconductor wafer 710C can be a logic wafer comprising logic dies that are configured to control memory operations of the memory dies.

In some embodiments, each test pad of at least one semiconductor wafer can be unexposed to an outside of the wafer stack formed by the semiconductor wafers 710A to 710C. There may be no exposed pads for test in one or more of the semiconductor wafers 710A to 710C. By way of example but not limitation, there are no exposed pads for test in the semiconductor wafer 710B sandwiched between the semiconductor wafers 710A and 710C. As another example, there are no exposed pads for test in all of the semiconductor wafers 710A to 710C. The proposed non-contact testing scheme can test a DUT on a semiconductor wafer even if each test pad electrically connected to the DUT is not exposed or accessible from the outside of the wafer stack.

In the embodiment shown in FIG. 7A, the antenna element 720A and the transponder 730A are disposed on the semiconductor wafer 710A, the antenna element 720B and the transponder 730B are disposed on the semiconductor wafer 710B, and the antenna element 720C and the transponder 730C are disposed on the semiconductor wafer 710C. Each of the antenna elements 720A to 720C can be implemented using the antenna element 120 shown in FIG. 1A, and each of the transponders 730A to 730C can be implemented using the transponder 130 shown in FIG. 1A.

For the semiconductor wafers 710A to 710C, the antenna elements 720A to 720C and the transponders 730A to 730C are embedded in the semiconductor device 704A. Therefore, the antenna elements 720A to 720C and the transponders 730A to 730C are not visible from the outside of the semiconductor device 704A (or the wafer stack). In some embodiments, the wafer stack (or the semiconductor device 704A) can be designed to expose the antenna elements and the transponders on the two sides thereof. For example, but not limitation, the antenna elements 720A and 720C and the transponder 730A and 730C on the side surface of the semiconductor device 704A. Therefore, the antenna elements 720A and 720C, and the transponder 730A and 730C are visible from the outside of the semiconductor device 704A.

The DUTs 740A to 740C in the wafer stack may be visible or not visible from the outside. When visible from the outside of the wafer stack, a DUT can be visually identified, and tested using a contact-based testing method or the proposed non-contact testing scheme. A DUT is not visible from the outside of the wafer stack when embedded in one semiconductor wafer or sandwiched between two semiconductor wafers. Although the DUT that is not visible from the outside is unable to be visually identified and tested using the contact-based testing method, the proposed non-contact testing scheme can be applied to test the DUT in a non-contact manner.

In operation, the wireless interrogation signal S_I sent by the RF reader 102 can be used to test the DUTs 740A/740B/740C placed on the semiconductor wafers 710A/710B/710C. Each of the DUTs 740A to 740C can be implemented using the DUT 140 shown in FIG. 1A. By way of example but not limitation, in addition to test parameters, test conditions, and/or test modes, the wireless interrogation signal S_I can further indicate the identification information of a DUT and/or the identification information of a semiconductor wafer where the DUT is located. Thus, the transponder on each semiconductor wafer can determine if the current test operation is intended for a DUT connected to the transponder according to an electrical signal coming from a corresponding antenna element.

Consider an example where the transponders 730A to 730C store the identification information of the DUTs 740A to 740C respectively. When the identification information indicated by the wireless interrogation signal S_I matches the identification information of the DUT 740B, the transponder 730B can determine that the identification information indicated by the wireless interrogation signal S_I matches the stored identification information, thereby triggering the DUT 740B and obtaining a corresponding response signal from the DUT 740B. Additionally or alternatively, in a case where the DUT 740B is implemented using the DUT architecture shown in FIG. 4, when the transponder 740B determines that the identification information indicated by the wireless interrogation signal S_I matches the identification information of a sub-unit under test of the DUT 740B, the transponder 740B can trigger this sub-unit under test and obtain a corresponding response signal.

In some embodiments, each transponder can be implemented using the architecture shown in FIG. 3, in which the controller of each transponder (not shown in FIG. 7A) can be used for storing and comparing the identification information. In some embodiments, the testing system 700A can employ the inductive coupling architecture shown in FIG. 6 to provide the wireless interrogation signal S_I to the antenna elements 720A/720B/720C. As those skilled in the art can appreciate the operation of the testing system 700A after reading the paragraphs directed to FIG. 1A to FIG. 6, similar description are not repeated here for brevity.

FIG. 7B illustrates an implementation of the testing system 100 shown in FIG. 1A in accordance with some embodiments of the present disclosure. The testing system 700B includes the RF reader 102 shown in FIG. 1A and a semiconductor device 704B. The semiconductor device 704B may include, but is not limited to, the semiconductor wafers 710B and 710C shown in FIG. 7A. The antenna element and the transponder used in the proposed testing scheme can be disposed on at least one of the semiconductor wafers 710B and 710C.

In the present embodiment, the semiconductor wafer 710B can includes multiple DUTs 740B, and the semiconductor wafer 710C can include multiple DUTs 740C. Before the semiconductor wafers 710B and 710C are bonded, each semiconductor wafer can be tested using a contact-based testing method (e.g., probe testing) or the proposed non-contact testing scheme. After the semiconductor wafers 710B and 710C are bonded to form a wafer stack, each semiconductor wafer or the wafer stack can be tested using the proposed non-contact testing scheme even if test pads for a DUT on the semiconductor wafer are not exposed to the outside.

Consider an example where the DUTs 740B and 740C become connected when the semiconductor wafers 710B and 710C are bonded. The DUTs 740B and 740C are electrically connected to each other through bonding pads PD_1 to PD_K (where K is a positive integer) that are used for signal transmission. The DUT 740B and the DUT 740C that are connected to each other can be regarded as a unitary DUT 740U in a wafer stack formed by the semiconductor wafers 710B and 710C. In other words, the DUT 740B can serve as a first portion of the DUT 740U, and the DUT 740C can serve as a second portion of the DUT 740U. The DUT 740U can be regarded as a DUT placed on the semiconductor wafer 710B; similarly, the DUT 740U can be regarded as a DUT placed on the semiconductor wafer 710C. Note that test pads for the DUT 740U (e.g. test pads for the DUTs 740B and 740C) may be invisible from or unexposed to the outside. For example, test pads for the semiconductor wafer 710B are embedded therewithin and therefore are inaccessible from the outside. Additionally, or alternatively, test pads for the semiconductor wafer 710C are embedded therewithin and therefore are inaccessible from the outside. The testing system 700B can test the DUT 740U at the wafer level even if the test pads for the DUT 740U are not exposed to the outside.

By way of example but not limitation, the semiconductor wafer 710B is a memory wafer, and the semiconductor wafer 710B is a logic wafer provided for the memory wafer. The memory wafer can be a dynamic random-access memory (DRAM) wafer that contains DRAM cells, and the logic wafer can include logic control circuit(s) or processor(s) (e.g., a central processing units (CPU) or a graphics processing unit (GPU)) for controlling memory operations of the DRAM cells. The RF reader 102 may send an RF signal (i.e., the wireless interrogation signal S_I) for testing the DUT 740U, and access the data of the DUT 740 via the antenna element 720C and the transponder 730C disposed on the logic wafer (i.e., the semiconductor wafer 710C). The DUT 740B (e.g., a DUT placed on the memory wafer) can be triggered in response to a stimulus signal generated by the transponder 730C through the electrical connection between the DUTs 740B and 740C. A response signal generated by the DUT 740B can be provided for the transponder 730C through the electrical connection between the DUTs 740B and 740C. In other words, the antenna element 720C and the transponder 730C can be used for testing not only the DUT 740C on the semiconductor wafer 710C, but also the DUT 740B on the semiconductor wafer 710B. The antenna element 720B and the transponder 730B may be optional.

Similarly, the antenna element 720B and the transponder 730B can be used for testing not only the DUT 740B on the semiconductor wafer 710B, but also the DUT 740C on the semiconductor wafer 710C. The antenna element 720C and the transponder 730C may be optional. With use of an antenna element and a transponder on one semiconductor wafer in a wafer stack, DUT(s) on each semiconductor wafer in the wafer stack can be tested. Antenna element(s) and transponder(s) on the other semiconductor wafer(s) can be optional. For example, but not limitation, it is sufficient to implement an antenna element and a transponder on a logic wafer in a wafer stack; there would be no need to implement an antenna element and a transponder on the other wafers (e.g. memory wafers) in the wafer stack.

In some embodiments, the respective scribe lines on the semiconductor wafers 710B and 710C are aligned with each other after the semiconductor wafers 710B and 710C are bonded. When an antenna element and/or a transponder is located in a corresponding scribe line (not shown), respective antennas and/or transponders on the semiconductor wafers 710B and 710C can be removed or destroyed simultaneously during the subsequent wafer dicing operation.

As those skilled in the art can appreciate the operation of the testing system 700B after reading the paragraphs directed to FIG. 1A to FIG. 7A, similar description are not repeated here for brevity.

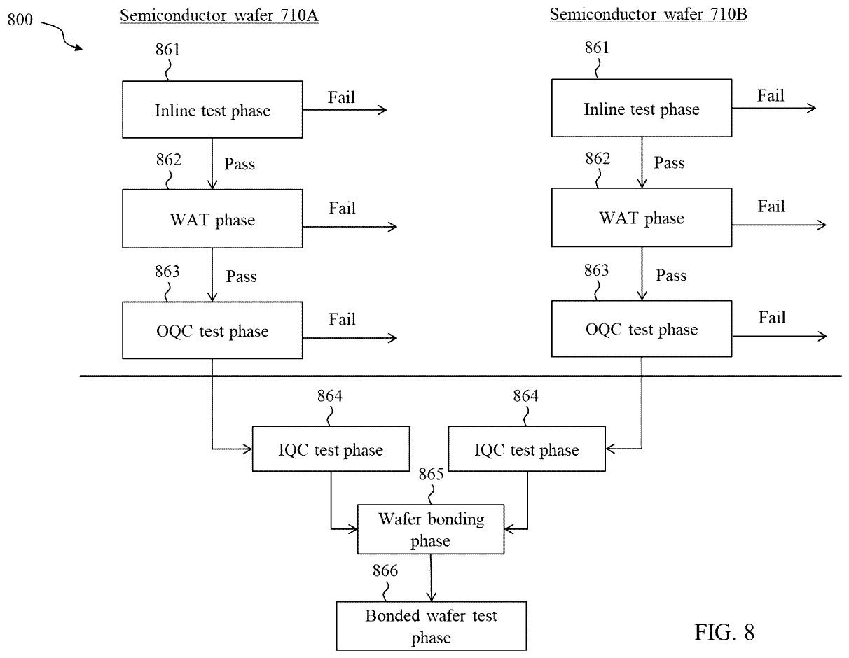

FIG. 8 is a diagram illustrating a workflow for integrating non-contact testing into wafer-on-wafer bonding in accordance with some embodiments of the present disclosure. For illustrative purposes, the workflow 800 is described with reference to the semiconductor wafers 710A and 710B shown in FIG. 7A. Those skilled in the art can appreciate that the workflow 800 can be used for testing the semiconductor wafers 710B and 710C shown in FIG. 7A and the semiconductor wafers 710B and 710C shown in FIG. 7B without departing from the scope of the present disclosure.

First, in the inline test phase 861, the testing architecture shown in FIG. 1A, FIG. 2 or FIG. 6 can be used to detect whether the semiconductor wafers 710A and 710B have defects or abnormalities in real time to ensure wafer yield. If the semiconductor wafer 710A/710B passes the inline test, the workflow 800 proceeds to the wafer acceptance test (WAT) phase 862; if the semiconductor wafer 710A/710B fails the inline test, the semiconductor wafer 710A/710B can be rejected from entering the wafer acceptance test phase 862. For example, wafers that fail the inline test can be sent back to the previous process step for repair.

In the wafer acceptance test phase 862, the testing architecture shown in FIG. 1A, FIG. 2 or FIG. 6 can be used to evaluate the electrical parameters of the semiconductor wafers 710A and 710B (e.g. resistance, capacitance or current-voltage characteristics) to ensure that circuits on the semiconductor wafers 710A and 710B meet the expected performance. If the semiconductor wafer 710A/710B passes the wafer acceptance test, the workflow 800 proceeds to the outgoing quality control (OQC) test phase 863; if the semiconductor wafer 710A/710B fails the wafer acceptance test, the semiconductor wafer 710A/710B can be rejected from entering the outgoing quality control test phase 863. For example, wafers that fail the wafer acceptance test can be sent back to the previous process step for repair.

In the outgoing quality control test phase 863, the testing architecture shown in FIG. 1A, FIG. 2 or FIG. 6 can be used to inspect any defects that may affect the final performance of the semiconductor wafers 710A and 710B, ensuring that the semiconductor wafers 710A and 710B meet expectations before shipment. If the semiconductor wafer 710A/710B passes the outgoing quality control test, the semiconductor wafer 710A/710B can be approved for shipment; if the semiconductor wafer 710A/710B fails the outgoing quality control test, the semiconductor wafer 710A/710B can be rejected for shipment. For example, wafers that fail the outgoing quality control test can be sent back to the previous process step for repair.

The aforementioned inline test, wafer acceptance test, and outgoing quality control test can be performed in the same wafer fabrication plant (fab). By way of example but not limitation, the semiconductor wafer 710A can be a logic wafer manufactured and tested in a logic wafer fab, while the semiconductor wafer 710B can be a memory wafer manufactured and tested in a memory wafer fab. After passing the outgoing quality control test, the semiconductor wafers 710A and 710B can be shipped to a wafer fab for wafer stacking.

In the wafer fab where wafer stacking is performed, the testing architecture shown in FIG. 1A, FIG. 2 or FIG. 6 can be used to conduct incoming quality control (IQC) tests on the semiconductor wafers 710A and 710B (i.e., the incoming quality control test phase 864) to ensure that the semiconductor wafer 710A/710B meets quality requirements before stacking. If the semiconductor wafer 710A/710B passes the incoming quality control test, the workflow 800 proceeds to the wafer bonding phase 865. After the semiconductor wafers 710A and 710B have been bonded, the testing architecture shown in FIG. 7A can be used to test the stacked semiconductor wafers 710A and 710B (i.e., the bonded wafer test phase 866).

As those skilled in the art can appreciate the operation of each testing phase in the workflow 800 after reading the above paragraphs directed to FIG. 1A to FIG. 7B, similar description is not repeated here for brevity.

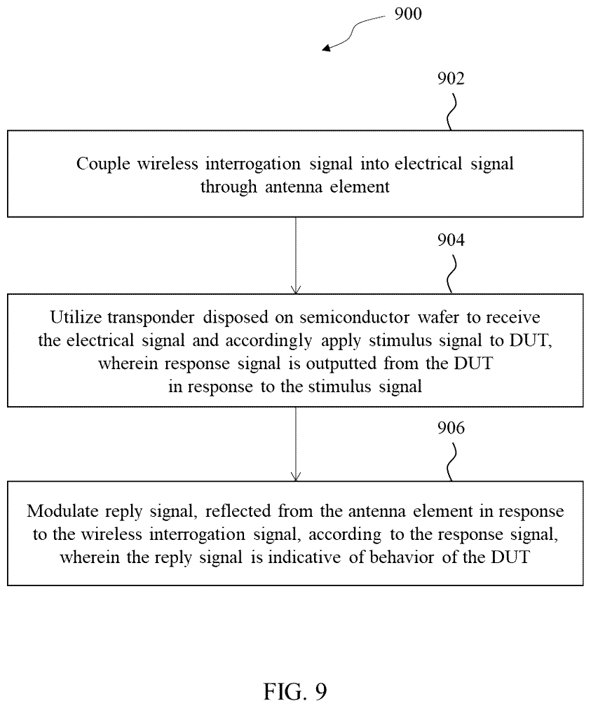

FIG. 9 is a flowchart of an exemplary method for testing a DUT on a semiconductor wafer in accordance with some embodiments of the present disclosure. For illustrative purposes, the method 900 is described with reference to the testing system 100 shown in FIG. 1A. Those skilled in the art will appreciate that the method 900 can be applied to the testing system 200 shown in FIG. 2, the testing system 600 shown in FIG. 6, and the testing system 700A shown in FIG. 7A, without departing from the scope of the present disclosure. Additionally, in some embodiments, the method 900 may include other operations. In some embodiments, operations of the method 900 can be performed in a different order and/or vary.

Referring to FIG. 9 and also to FIG. 1A, at operation 902, a wireless interrogation signal is coupled into an electrical signal through an antenna element. For example, the wireless interrogation signal S_I emitted by the RF reader 102 is coupled into the electrical signal S_E through the antenna element 120.

At operation 904, a transponder disposed on the semiconductor wafer is utilized to receive the electrical signal and accordingly apply a stimulus signal to the DUT. A response signal is outputted from the DUT in response to the stimulus signal. For example, the transponder 130 can receive the electrical signal S_E and accordingly apply the stimulus signal S_S to the DUT 140, thereby triggering the DUT 140 to generate the response signal S_R.

At operation 906, a reply signal is modulated according to the response signal. The reply signal is reflected from the antenna element in response to the wireless interrogation signal, and indicates a behavior of the DUT. For example, the transponder 130 can modulate a reply signal, reflected from the antenna element 120 back to the RF reader 102, according to the response signal S_R, thereby generating a modulated reply signal (i.e., the modulated RF signal S_M). The reply signal is generated in response to the wireless interrogation signal S_I that is applied to the antenna element 120, and the modulated reply signal can indicate the behavior of the DUT 140.

In some embodiments, power provided for the DUT can be delivered according to the electrical signal. For example, the transponder 130 can deliver power to the DUT 140 according to the electrical signal S_E. In some embodiments, the transponder can be disposed on a surface of the semiconductor wafer where the DUT is located, and can be sandwiched between the semiconductor wafer and another semiconductor wafer that are stacked one on top of the other. For example, the transponder 130 and the DUT 140 can be disposed on the same surface of the semiconductor wafer 110, and the transponder 130 can be sandwiched between the stacked semiconductor wafer 110 and another semiconductor wafer (e.g. the stacked semiconductor wafers 710A and 710B shown in FIG. 7A).

As those skilled in the art can appreciate the operation of the method 900 after reading the above paragraphs directed to FIG. 1A to FIG. 8, further description is omitted here for brevity.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor wafer, comprising a plurality of regions, wherein each of the regions comprises one or more dies;
an antenna element, disposed in one of the regions where a device under test (DUT) is located, the antenna element being arranged to couple a radio frequency (RF) signal into an electrical signal; and
an RF transponder, disposed in the one of the regions and coupled to the antenna element and the DUT, the RF transponder being configured to send a stimulus signal to the DUT in response to the electrical signal received from the antenna element, and drive the antenna element to output a modulated RF signal according to a response signal received from the DUT, wherein the response signal is generated from the DUT in response to the stimulus signal.

2. The semiconductor device of claim 1, wherein the modulated RF signal changes in response to a change in a load impedance on the antenna element, and the RF transponder is configured to adjust the load impedance on the antenna element according to the response signal.

3. The semiconductor device of claim 1, wherein the RF transponder comprises:
a controller, coupled to the DUT, the controller being configured to process the response signal to generate a data signal; and
a modulator circuit, coupled to the antenna element and the controller, the modulator circuit being configured to switch between different impedance states according to the data signal, and accordingly drive the antenna element to output the modulated RF signal.

4. The semiconductor device of claim 1, wherein the RF transponder comprises:
a demodulator circuit, coupled to the antenna element, the demodulator circuit being configured to demodulate the electrical signal to generate a command signal; and
a controller, coupled to the demodulator circuit and the DUT, the controller being configured to process the command signal to generate the stimulus signal to trigger the DUT.

5. The semiconductor device of claim 1, wherein the RF transponder is further configured to deliver power to the DUT according to the electrical signal.

6. The semiconductor device of claim 1, wherein the RF transponder comprises:
an energy harvesting circuit, coupled to the antenna element, the energy harvesting circuit being configured to capture energy from the electrical signal to generate a power signal; and
a controller, coupled to the energy harvesting circuit and the DUT, the controller being configured to provide the power signal to the DUT.

7. The semiconductor device of claim 1, further comprising:
a second semiconductor wafer, stacked on a surface of the first semiconductor wafer.

8. The semiconductor device of claim 7, wherein each of the first semiconductor wafer and the second semiconductor wafer is a memory wafer comprising memory dies.

9. The semiconductor device of claim 7, wherein the second semiconductor wafer is a memory wafer comprising memory dies, and the first semiconductor wafer is a logic wafer comprising logic dies configured for controlling memory operation of the memory dies.

10. The semiconductor device of claim 7, wherein the first semiconductor wafer and the second semiconductor wafer are stacked to form a wafer stack; each test pad of at least one of the first semiconductor wafer and the second semiconductor wafer is unexposed to an outside of the wafer stack.

11. The semiconductor device of the claim 7, wherein a first portion of the DUT is placed on the first semiconductor wafer, and a second portion of the DUT is placed on the second semiconductor wafer; the first portion and the second portion of the DUT are connected to each other.

12. The semiconductor device of claim 1, wherein the DUT comprises a first sub-unit under test and a second sub-unit under test; when the RF transponder is configured to activate one of the first sub-unit under test and the second sub-unit under test according to the stimulus signal, the other of the first sub-unit under test and the second sub-unit under test is inactivated.

13. The semiconductor device of claim 1, wherein the RF transponder is located in a scribe line on the first semiconductor wafer.

14. A testing system, comprising:
a first semiconductor wafer, comprising a plurality of regions, wherein each of the regions comprises one or more dies;
a radio frequency (RF) reader, arranged for sending a wireless interrogation signal to the first semiconductor wafer;
an antenna element, disposed in one of the regions where a device under test (DUT) is located, the antenna element being arranged to couple the wireless interrogation signal into an electrical signal; and
an RF transponder, disposed in the one of the regions and coupled to the antenna element and the DUT, the RF transponder being configured to send a stimulus signal to the DUT in response to the electrical signal, and drive the antenna element to output an modulated RF signal according to a response signal received from the DUT, wherein the response signal is generated from the DUT in response to the stimulus signal, and the modulated RF signal is reflected from the antenna element back to the RF reader.

15. The testing system of claim 14, wherein the modulated RF signal changes in response to a change in a load impedance on the antenna element, and the RF transponder is configured to adjust the load impedance on the antenna element according to the response signal.

16. The test system of claim 14, wherein the RF reader and the RF transponder interact through inductive coupling.

17. The testing system of claim 14, further comprising:
a second semiconductor wafer, stacked on a surface of the first semiconductor wafer.

18. A method for testing a device under test (DUT) on a semiconductor wafer, comprising:
coupling a wireless interrogation signal into an electrical signal through an antenna element;
utilizing a transponder disposed on the semiconductor wafer to receive the electrical signal and accordingly apply a stimulus signal to the DUT, wherein a response signal is outputted from the DUT in response to the stimulus signal; and
modulating a reply signal, reflected from the antenna element in response to the wireless interrogation signal, according to the response signal, wherein the reply signal is indicative of a behavior of the DUT.

19. The method of claim 18, further comprising:
delivering power to the DUT according to the electrical signal.

20. The method of claim 18, wherein the transponder is disposed on a surface of the semiconductor wafer where the DUT is located, and is sandwiched between the semiconductor wafer and another semiconductor wafer stacked one on top of the other.
